(19) United States
(12) Patent Application Publication
(10) Pub. No.: US 2026/0210234 A1
(43) Pub. Date: Jul. 23, 2026

(54) SYSTEMS AND METHODS FOR MULTIPLE MECHANICAL CALIPER MEASUREMENTS

(71) Applicant: Schlumberger Technology Corporation, Sugar Land, TX (US)

(72) Inventors: Xiao Lin Zhang, Clamart (FR); Jean-Luc Le Calvez, Clamart (FR); Martin Carles, Clamart (FR); Huu Tinh Hoang, Clamart (FR); Laetitia Comparon, Clamart (FR); Thomas Berard, Clamart (FR); Fatma Dhawefi, Clamart (FR); Laura Lima Angelo dos Santos, Clamart (FR)

(21) Appl. No.: 19/032,138

(22) Filed: Jan. 20, 2025

(51) Int. Cl. E21B 47/08; G01B 3/38; G01B 5/12

(52) U.S. Cl. CPC E21B 47/08; G01B 3/38; G01B 5/12

(57) ABSTRACT

Systems and methods disclosed herein are generally directed to an interpretation system that may receive measurements from multi-finger caliper tools and output various properties of a wellbore based on the measurements and/or models (e.g., computer models having algorithms) associated with the multi-finger caliper tools. For example, the interpretation system may generate and output defect maps (e.g., maps of defects according to axial position and circumferential position) based on an interpretation of the measurements. In another example, the interpretation system may determine a state of the wellbore based on the interpretation. If the state is clear, then the interpretation system may instruct one or more components of the hydrocarbon well site to initiate production operations. If the state is not clear (e.g., corrosion), then the interpretation system may identify an interval of interest within the wellbore and/or perform a corrective action at the interval of interest.

### BACKGROUND

The present disclosure generally relates to monitoring various properties at a hydrocarbon well site. More specifically, the present disclosure relates to providing an interpretation system for determining various properties of wellbores within the hydrocarbon well site based on multi-finger caliper measurements taken from the hydrocarbon well site and one or more models.

Prior to and/or during production operations, information related to the hydrocarbons extracted from a hydrocarbon well and/or related to equipment used to transport, store, or process the extracted hydrocarbons may be gathered at the well (e.g., the well site) or at various locations along a network of pipelines. In certain instances, it may be beneficial to determine various properties of a wellbore before, during, and/or after production operations. To determine the properties, measurements indicative of an interior surface and/or a radii of the wellbore may be generated by one or more multi-finger caliper tools that traverse through the wellbore. As such, it may be beneficial to obtain accurate predictions for various wellbore properties by interpretating measurements from the multi-finger caliper tools.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, a system may include a multi-finger caliper tool configured to be positioned within a wellbore of a hydrocarbon site, wherein the multi-finger caliper tool configured to generate measurements indicative of an interior surface of the wellbore, a component coupled to the multi-finger caliper tool and configured to adjust a position of the multi-finger caliper tool within the wellbore, and a computing system communicatively coupled to the multi-finger caliper tool. The computing system may include processing circuitry and memory storing instructions. The instructions, when executed by the processing circuitry, may cause the processing circuitry to perform an autonomous workflow to instruct the component to adjust the position of the multi-finger caliper tool within the wellbore to generate the measurements, convert the measurements into radii values based on at least one model of a plurality of models, and generate corrected radii values based on the radii values and a second model of the plurality of models. The instructions when executed by the processing circuitry, may also cause the processing circuitry to generate a defect map indicative of a portion of the wellbore based on the corrected radii values and instruct a display to display the defect map.

In an embodiment, a method may include by processing circuitry, instructing a component of a hydrocarbon well site to adjust a position of a multi-finger caliper tool within a wellbore of a hydrocarbon well site to generate a set of measurements, receiving the set of measurements indicative of an interior surface of a portion of the wellbore from the multi-finger caliper tool, and converting the set of measurements into a set of radii values based on at least one model of a plurality of models. The method may also include generating, via the processing circuitry, a set of corrected radii values based on the set of radii values and a second model of the plurality of models and generating, via the processing circuitry, a defect map indicative of the portion of the wellbore based on the set of corrected radii values. The method may also include identifying, via the processing circuitry, one or more defects within the portion of the wellbore based on the defect map and instructing, via the processing circuitry, a display to display a graph including the set of corrected radii values and the defect map.

In an embodiment, a system may include a multi-finger caliper tool configured to be positioned within a wellbore of a hydrocarbon site, wherein the multi-finger caliper tool configured to generate measurements indicative of an interior surface of the wellbore, a component coupled to the multi-finger caliper tool and configured to adjust a position of the multi-finger caliper tool, and a computing system communicatively coupled to the multi-finger caliper tool. The computing system may include processing circuitry and memory storing instructions. The instructions, when executed by the processing circuitry may cause the processing circuitry to perform an autonomous workflow to perform a first calibration of the multi-finger caliper tool by instructing the component to adjust the position of the multi-finger caliper tool through one or more pipes with known diameters to generate first calibration measurements while traversing through the one or more pipes, instruct the component to adjust the position of the multi-finger caliper tool within the wellbore to generate the measurements while traversing through the wellbore, perform a second calibration of the multi-finger caliper tool by instructing the component to adjust the position of the multi-finger caliper tool through the one or more pipes with known diameters to generate second calibration measurements while traversing through the one or more pipes. The instructions, when executed by the processing circuitry may cause the processing circuitry to convert the measurements into radii values based on the first calibration measurements, the second calibration measurements, and at least one model of a plurality of models, generate corrected radii values based on a second model of the plurality of models, generate a defect map indicative of a portion of the wellbore based on the corrected radii values, and instruct a display to display the defect map.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 illustrates a schematic diagram of an example hydrocarbon site that may produce and process hydrocarbons, in accordance with embodiments of the present disclosure;

FIG. 2 illustrates a block diagram of an interpretation system communicatively coupled to a multi-finger caliper tool used in the hydrocarbon site of FIG. 1, in accordance with embodiments of the present disclosure;

FIG. 3 illustrates a flow diagram of the interpretation system of FIG. 2 operating the multi-finger caliper tool and interpretating the measurements from the multi-finger caliper tool, in accordance with embodiments of the present disclosure;

FIG. 4 illustrates a graphical user interface (GUI) of an electronic display presenting a defect analysis technique implemented by the interpretation system of FIG. 2, in accordance with embodiments of the present disclosure;

FIG. 5 illustrates a model used by the interpretation system of FIG. 2 to determine various properties of the wellbore, in accordance with embodiments of the present disclosure;

FIG. 6 illustrates a flow chart of an example method for aligning measurements from the multi-finger caliper tool and identifying defects and/or a repetition of the defects by the interpretation system of FIG. 2, in accordance with embodiments of the present disclosure; and

FIG. 7 illustrates a GUI of an electronic display presenting defect maps and a defect repetition index generated by the interpretation system of FIG. 2, in accordance with embodiments of the present disclosure.

### DETAILED DESCRIPTION

Certain embodiments commensurate in scope with the present disclosure are summarized below. These embodiments are not intended to limit the scope of the disclosure, but rather these embodiments are intended only to provide a brief summary of certain disclosed embodiments. Indeed, the present disclosure may encompass a variety of forms that may be similar to or different from the embodiments set forth below.

As used herein, the term “coupled” or “coupled to” may indicate establishing either a direct or indirect connection (e.g., where the connection may not include or include intermediate or intervening components between those coupled) and is not limited to either unless expressly referenced as such. The term “set” may refer to one or more items. Wherever possible, like or identical reference numerals are used in the figures to identify common or the same elements. The figures are not necessarily to scale and certain features and certain views of the figures may be shown exaggerated in scale for purposes of clarification.

As used herein, the terms “inner” and “outer”; “up” and “down”; “upper” and “lower”; “upward” and “downward”; “above” and “below”; “inward” and “outward”; and other like terms as used herein refer to relative positions to one another and are not intended to denote a particular direction or spatial orientation. The terms “couple,” “coupled,” “connect,” “connection,” “connected,” “in connection with,” and “connecting” refer to “in direct connection with” or “in connection with via one or more intermediate elements or members.”

Furthermore, when introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment,” “an embodiment,” or “some embodiments” of the present disclosure are not intended to be interpreted as excluding the existence of additional embodiments that also incorporate the recited features. Furthermore, the phrase A “based on” B is intended to mean that A is at least partially based on B. Moreover, unless expressly stated otherwise, the term “or” is intended to be inclusive (e.g., logical OR) and not exclusive (e.g., logical XOR). In other words, the phrase A “or” B is intended to mean A, B, or both A and B.

Hydrocarbon well sites (e.g., hydrocarbon wells, wells) may include a number of components that facilitate the extraction, processing, and distribution of hydrocarbons (e.g., oil) from a well or well site. For example, the hydrocarbon well site may include one or more wellbores (e.g., boreholes) extending to respective subterranean reservoirs. The hydrocarbon well site may also include one or more multi-finger caliper tools that traverse through the wellbore, and generate measurements indicative of an interior surface of the wellbore, radii values of the wellbore, and/or corrosion indicators corresponding to the wellbore. The wellbore may include various tubing, conduits, casings, liners, and strings used at the hydrocarbon well site, such as directly in a wellbore and/or coupled to a wellbore via a wellhead, a Christmas tree, a distribution manifold, or any combination thereof. As used herein, the wellbore may refer to any of the tubing, conduits, casings, liners, and strings that may couple to the wellbore and/or positioned directly within the wellbore. However, the measurements from the multi-finger caliper tools may include discrepancies in depth, radius, and/or azimuth. As such, several processing steps may be performed to interpret (e.g., process) the measurements from the multi-finger caliper tools and generate various properties of the wellbore. For example, the processing steps may identify defects caused by an axial tool scratching or gouging the interior surface of the wellbore, a single-point defects caused by corrosion, or any combination thereof. The wellbore may include tens to hundreds of defects and verifying each defect across different multi-finger caliper measurements may be both time-intensive and resource-intensive. Indeed, obtaining various properties of the wellbore based on measurements from the multi-finger caliper tools may be difficult, resource-intensive, and/or time-consuming.

With this in mind, embodiments of the present disclosure are generally directed to an interpretation system (e.g., a processor-based monitoring and analysis system and/or computing device) that may receive measurements from the multi-finger caliper tools and output various properties of the wellbore based on the measurements and/or models (e.g., computer models having algorithms) associated with the multi-finger caliper tools. Although the embodiments described below are presented in context of a wellbore, the embodiments may be used for any tubing, piping, or conduit that may be inspected by a multi-finger caliper tool. Additionally, any models discussed below are intended to include various computer models, machine learning, and/or artificial intelligence (AI). The computer models may include three-dimensional models of the wellsite, geological formations, and the wellbore. The computer models may include computation fluid dynamics (CFD) models, reservoir simulation models, geological models, digital twin models for equipment and tools (e.g., multi-finger caliper tools), or any combination thereof. For example, the interpretation system may interpret measurements from the multi-finger caliper tools using one or more models without user intervention. In another example, the interpretation system may generate and output a corrosion analysis of the wellbore and/or defect maps (e.g., maps of defects according to axial position and circumferential position) based on the interpretation. Still in another example, the interpretation system may determine a state of the wellbore and/or the hydrocarbon well site based on the interpretation. If the state is clear, then the interpretation system may instruct one or more components of the hydrocarbon well site to initiate production operations and/or transmit a notification to a user device indicative of the state. If the state is not clear (e.g., error), then the interpretation system may identify an interval of interest within the wellbore (e.g., a location within the wellbore, a position within the wellbore) based on the interpretation. The interpretation system may transmit a notification indicative of the state, the interval of interest, a tool of interest, or any combination thereof, to a user device and/or an electronic display. The interpretation system may instruct one or more components to initiate repair of the wellbore at the interval of interest, transmit a notification indicative of changing a tool positioned within the wellbore, control one or more aspects of the hydrocarbon set site (e.g., adjusting a valve position, adjusting a pump or compressor speed, and/or adjusting chemical injection into the well) and/or instruct the tool to return to the surface, and so on. As such, the interpretation system may improve production operations within the hydrocarbon well site.

Keeping this in mind, in certain embodiments, the interpretation system may perform a calibration of a multi-finger caliper tool in three steps: Master-tool Calibration, Before-Job Calibration, and After-Job Calibration. During the Master Calibration, the raw electrical measurements of the multi-finger caliper tool may be converted to radii values based on a relationship established by running the tool through pipes of known diameters and at various temperatures. The calibration may be performed as part of a quality control step of the multi-finger caliper tool to identify deviations of the multi-finger caliper tool, check attributes of the multi-finger caliper tool against other quality indices, thereby improving and/or verifying the accuracy and/or reliability of measurements generated by the multi-finger caliper tool. During the Before-Job Calibration and/or the After-Job Calibration, the raw electrical measurements of the multi-finger caliper tool may be converted to radii values based on a relationship established by running the tool through pipes of known diameters at ambient temperature. As such, the interpretation system may correct the measurements for errors introduced by tool eccentricity, finger wear, finger offset, and so on. The interpretation system may store the measurements from the Master-tool Calibration, Before-Job Calibration, and After-Job Calibration and the respective relationships as one or more models within a memory and/or a storage device.

After receiving measurements from the multi-finger caliper tool, the interpretation system may apply one or more models to the measurements to further adjust (e.g., auto-correct) the measurements without user intervention. For example, the interpretation system may apply at least one model (e.g., a first model) indicative of a relationship established by running the multi-finger caliper tool through pipes of known diameter to the measurements in order to convert electrical measurements into radii values and/or reduce or eliminate raw measurement errors introduced by the multi-finger caliper tool. In another example, the interpretation system may adjust the radii values to remove outliers based on a second model indicative of an elliptical shape. The elliptical shape may be representative of an internal bore of the wellbore.

With the adjusted measurements, the interpretation system may generate and output various properties of the wellbore based on additional models without user intervention. For example, the interpretation system may identify defects (e.g., protrusions, grooves, corrosion, cracks, holes, etc.) along the interior surface of the wellbore based on the adjusted radii values (e.g., corrected radii values) and a repetition frequency of each defect across different multi-finger caliper measurements to verify (e.g., validate) the defect. The interpretation may identify multiple defects within a portion of the wellbore. The interpretation system may group the defects based on a relative distance between each defect. The interpretation system may also determine a wellbore strength of the portion of the wellbore based on the grouped defects and/or a third model indicative of mechanical and/or stress considerations. The interpretation system may also generate and output the corrosion analysis of the wellbore based on the adjusted radii values and a threshold radii value. The interpretation system may output a summary table with a corrosion state and/or properties for each collar and joint of the wellbore. The corrosion state may include a percentage of corrosion, a thickness of the corrosion, a length of the corrosion, and so on. The properties may include a minimum inner diameter, a maximum penetration, and so on. As such, the interpretation system may generate and output various properties of the wellbore based on the measurements and/or the models.

In certain instances, the interpretation system may also generate a composite measurement with enhanced resolution (e.g., high resolution) by identifying and merging measurements from different multi-finger caliper tools taken from the same portion of the wellbore and under different conditions. For example, the interpretation system may align the measurements in depth and/or azimuth. The interpretation system may then generate the composite measurement by merging the aligned measurements. The interpretation system may interpret the composite measurement to identify various properties of the wellbore based on the models. As such, the interpretation system may output various properties of the wellbore without user intervention.

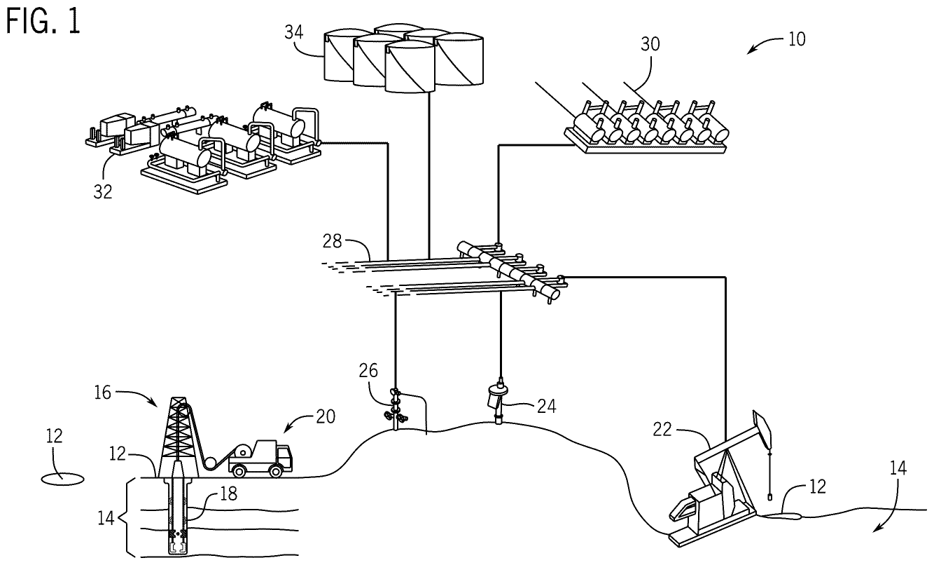

By way of introduction, FIG. 1 illustrates a schematic diagram of an example hydrocarbon site 10 where hydrocarbon products, such as crude oil and natural gas, may be extracted from the ground, processed, and stored. Datasets related to the operation of the hydrocarbon site 10 may be employed in accordance with the present embodiments. As shown in FIG. 1, the hydrocarbon site 10 may include a number of components or facilities that correspond to wells, processing facilities, collection components, distribution networks, and the like. During the design phase of planning for the types of components to use at the hydrocarbon site 10, the locations of the components at the hydrocarbon site 10, and other design properties, a variety of factors are taken under consideration.

The hydrocarbon site 10 may include a number of wells 12 disposed within a geological formation. As used herein, wells 12 may generally refer to physical components such as the drilling platform 16 and wellbore 18 and/or the general area of the reservoir in which extraction is desired (e.g., a reservoir well section). The drilling operations may include drilling the wellbore 18, injecting drilling fluids into the wellbore 18, performing casing operations within the wellbore 18, and the like. For example, the present embodiments are directed to an interpretation system that identifies certain areas of the wellbore 18 for perforation based on the first set of measurements and/or the second set of measurements to improve the drilling and/or production operations. In addition to including the drilling platform 16, the hydrocarbon site 10 may include surface equipment 20 that may carry out certain operations, such as cement installation operation, well logging operations to detect conditions of the wellbore 18, and the like. As such, the surface equipment 20 may include equipment that store cement slurries, drilling fluids, displacement fluids, spacer fluids, chemical wash fluids, and the like. The surface equipment 20 may include piping and other materials used to transport the various fluids described above into the wellbore 18. The surface equipment 20 may also include pumps and other equipment (e.g., batch mixers, centrifugal pumps, liquid additive metering systems, tanks, etc.) that may fill in the interior of a casing string with the fluids discussed above.

In addition to the equipment used for drilling operations, the hydrocarbon site may include a number of well devices that may control the flow of hydrocarbons being extracted from the wells 12. For instance, the well devices in the hydrocarbon site 10 may include pumpjacks 22, submersible pumps 24, well trees 26, and the like. The pumpjacks 22 may mechanically lift hydrocarbons (e.g., oil) out of the well 12 when a bottom hole pressure of the well 12 is not sufficient to extract the hydrocarbons to the surface. The submersible pump 24 may be an assembly that may be submerged in a hydrocarbon liquid that may be pumped. As such, the submersible pump 24 may include a hermetically sealed motor, such that liquids may not penetrate the seal into the motor. Further, the hermetically sealed motor may push hydrocarbons from underground areas or the reservoir to the surface. The well trees 26 may be an assembly of valves, spools, and fittings used for natural flowing wells. As such, the well trees 26 may be used for an oil well, gas well, water injection well, water disposal well, gas injection well, condensate well, and the like. By way of reference, the wells 12 may be part of a first hierarchical level and the well devices that extract hydrocarbons from the wells 12 may be part of a second hierarchical level above the first hierarchical level. Each hierarchical level may include a number of components and the presently disclosed techniques may account for these levels when determining the design plans for the hydrocarbon site 10.

After the hydrocarbons are extracted from the surface via the well devices, the extracted hydrocarbons may be distributed to other devices via a network of pipelines 28. That is, the well devices of the hydrocarbon site 10 may be connected together via a network of pipelines 28. In addition to the well devices described above, the network of pipelines 28 may be connected to other collecting or gathering components, such as wellhead distribution manifolds 30, separators 32, storage tanks 34, and the like.

In some embodiments, the pumpjacks 22, the submersible pumps 24, well trees 26, wellhead distribution manifolds 30, separators 32, and storage tanks 34 may be connected together via the network of pipelines 28. The wellhead distribution manifolds 30 may collect the hydrocarbons that may have been extracted by the pumpjacks 22, the submersible pumps 24, and the well trees 26, such that the collected hydrocarbons may be routed to various hydrocarbon processing or storage areas in the hydrocarbon site 10. The separator 32 may include a pressure vessel that may separate well fluids produced from oil and gas wells into separate gas and liquid components. For example, the separator 32 may separate hydrocarbons extracted by the pumpjacks 22, the submersible pumps 24, or the well trees 26 into oil components, gas components, and water components. After the hydrocarbons have been separated, each separated component may be stored in a particular storage tank 34. The hydrocarbons stored in the storage tanks 34 may be transported via the pipelines 28 to transport vehicles, refineries, and the like.

In certain instances, the hydrocarbons may corrode an interior surface of the wellbore 18, which may weaken portions of the wellbore 18 over time. For example, the corrosion may weaken a tubing, casing, and/or liner of the wellbore 18. In other instances, tools may be placed into the wellbore 18 before, during, and/or after production operations. As the tools traverse within the wellbore 18, the tools may scrape (e.g., mark, scratch) an interior surface of portion of the wellbore 18, which may decrease the strength of the wellbore 18.

Although the hydrocarbon site 10 is described above with certain components, it should be understood that the hydrocarbon site 10 may include additional, fewer, or different components. For example, although discussed above in relation to a hydrocarbon site 10 on land, present embodiments may also include analysis of off-shore hydrocarbon sites 10 and the components thereof. That is, the embodiments described herein are directed to identifying intervals of interest for any suitable hydrocarbon site that may include various types of components that are related to the production and distribution of hydrocarbons. In this way, the components depicted in FIG. 1 are provided as an example context in which the embodiments described herein may be implemented. As such, the embodiments of this disclosure should not be limited to the components listed in FIG. 1.

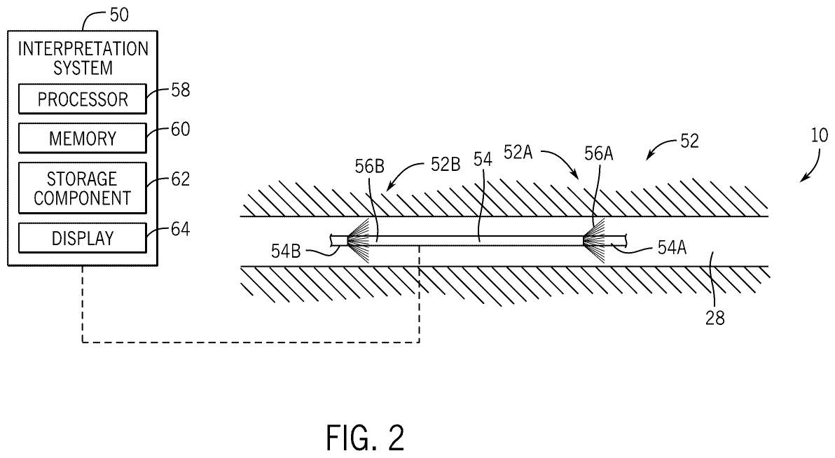

Keeping this in mind, the present embodiments described herein may include systems and methods for determining various properties of the wellbore 18, such as tubing, casing, and/or liners of the wellbore 18, before and/or during production operations. For example, the interpretation system 50, as presented in FIG. 2, may receive at least two sets of measurements from a multi-finger caliper tool 52, as presented in FIG. 2, interpret the measurements, and determine various properties of the wellbore 18 according to a process that will be described in greater detail below with respect to FIGS. 2-7.

Referring now to FIG. 2, the multi-finger caliper tool 52 may include a body portion 54, a first tool portion 52A having a first array of fingers 56A coupled to a first body portion 54A, and a second tool portion 52B having a second array of fingers 56B coupled to a second body portion 54B (collectively referred to herein as an “array of fingers 56” and a “body portion 54”). As illustrated, the body portion 54 may couple to and/or support the array of fingers 56. The multi-finger caliper tool 52 may include any suitable number of portions 52 and/or arrays of fingers 56. Each array of fingers 56 may include any suitable number of fingers that transitions between a collapsed configuration and an extended configuration. For example, each of the first and second arrays of fingers 56A and 56B may include equal to or greater than 10, 20, 30, 40, 50, 60, 70, 80, 90, or 100 fingers arranged circumferentially about a central axis of the respective first and second tool portions 52A and 52B. The collapsed configuration has the first and second arrays of fingers 56A and 56B substantially flush and/or recessed into a surface of the first and second tool portions 52A and 52B, such that the first and second arrays of fingers 56A and 56B are substantially parallel with the central axis. In contrast, the extended configuration has the first and second arrays of fingers 56A and 56B angled outward away from the surface of the first and second tool portions 52A and 52B, such that the first and second arrays of fingers 56A and 56B are oriented at an acute angle of about 10 to 80 degrees, 20 to 70 degrees, or 30 to 60 degrees relative to the central axis.

The finger openings may be converted into an electrical measurement by a linear variable displacement transducer of the multi-finger caliper tool 52. In the collapsed configuration, the array of fingers 56 may be positioned proximate to the body portion 54. To transition to the extended configuration, the array of fingers 56 may extend radially from the body portion 54. In the extended configuration, the array of fingers 56 contacts an interior surface of the wellbore 18 and generates a measurement indicative of the interior surface of the portion of the wellbore 18. The measurement generally varies in response to variations in the interior surface, including variations in overall diameter and variations caused by surface defects (e.g., protrusions, grooves, cracks, holes, corrosion, etc.), as the multi-finger caliper tool 52 extends lengthwise along the wellbore 18 in an axial direction of movement.

Movement of the multi-finger caliper tool 52 may be controlled by a component positioned at the surface of the hydrocarbon site 10. For example, the component may include a winch positioned outside of the wellbore 18. It may be understood that discussion of the movement of the multi-finger caliper tool 52 to perform passes within the wellbore 18 and/or traverse through a portion of the wellbore 18 may refer to the component controlling movement of the multi-finger caliper tool 52 within the wellbore 18.

With the foregoing in mind, the multi-finger caliper tool 52 may perform one or more passes in the axial direction (e.g., first axial direction and/or opposite second axial direction) through the wellbore 18 in the extended configuration of the array of fingers 56. For example, as the multi-finger caliper tool 52 traverses through the wellbore 18, the array of fingers 56 may scan the interior surface of the wellbore 18 and generate electrical measurements indicative of the radii of the wellbore 18. For example, a first array of fingers 56A may generate a first set of measurements for a portion of the wellbore 18 and the second array of fingers 56B may generate a second set of measurements for the portion of the wellbore 18. As such, the multi-finger caliper tool 52 may generate two sets of measurements for the same portion of the wellbore 18.

In certain instances, the multi-finger caliper tool 52 may perform one or more passes through portions of the wellbore 18 (e.g., intervals of interest of a tubing, casing, and/or a liner of the wellbore 18). The multi-finger caliper tool 52 may pass through the intervals of interest at various speeds to generate additional sets of measurements. In other instances, different multi-finger caliper tools 52 may perform a pass through the portion of the wellbore 18 (e.g., the interval of interest) to generate the additional sets of measurements. Increasing the number of measurements may improve robustness and/or improve reliability of the interpretation and/or the various properties of the wellbore determined by the interpretation system 50.

The multi-finger caliper tool 52 may transmit the measurements (e.g., the first set of measurements, the second set of measurements) to the interpretation system 50. The interpretation system 50 may include any suitable computing device, cloud-computing device, or the like and may include various components to perform various analysis operations. As shown in FIG. 2, the interpretation system 50 may include a processor 58, a memory 60, a storage component 62, a display 64, and the like. The processor 58 may be any type of computer processor or microprocessor capable of executing computer-executable code. The memory 60 and the storage component 62 may be any suitable articles of manufacture that can serve as media to store processor-executable code, data, or the like. For example, the memory 60 and/or storage component 62 may store one or more models (e.g., algorithms, machine learning models), relationships, or both that may be used for interpretating measurements from the multi-finger caliper tool 52. In another example, the memory 60 and/or the storage component 62 may store previous interpretations performed by the processor 58 and/or measurements from the multi-finger caliper tool 52. These articles of manufacture may represent non-transitory computer-readable media (i.e., any suitable form of memory or storage) that may store the processor-executable code used by the processor 58 to perform the presently disclosed techniques. The memory 60 and the storage component 62 may also be used to store data received via I/O ports, data analyzed by the processor 58, or the like.

The display 64 may include any type of electronic display such as a liquid crystal display, a light-emitting-diode display, and the like. As such, data acquired via the I/O ports and/or data analyzed by the processor 58 may be presented on the display 64, such that the interpretation system 50 may present production datasets related to operations of the hydrocarbon site 10 for view. In certain embodiments, the display 64 may be a touch screen display or any other type of display capable of receiving inputs from an operator. Although the interpretation system 50 is described as including the components presented in FIG. 2, the interpretation system 50 should not be limited to including the components listed in FIG. 2. Indeed, the interpretation system 50 may include additional or fewer components than described above. In certain embodiments, the interpretation system 50 may be described as a processor-based monitoring and analysis system, a control system or controller, or any combination thereof. The interpretation system 50 may be integrated within and/or coupled to a primary control system for the hydrocarbon site 10 of FIG. 1, and thus the measurements by the multi-finger caliper tool 52 may be used for control of various equipment (e.g., valves, pumps, compressors, separators, downhole tools, etc.) to improve operation of the hydrocarbon site 10.

With the foregoing in mind, the interpretation system 50 may adjust the measurements from the multi-finger caliper tool 52 without user intervention. For example, the interpretation system 50 may convert electrical measurements from the multi-finger caliper tool 52 into radii values based on at least one model (e.g., first model) indicative of respective relationships generated during a calibration process. Using the model, the interpretation system 50 may also reduce or eliminate raw measurement errors introduced by the multi-finger caliper tool 52, such as errors created by tool limitations and/or operational aspects. For example, the tool limitations may include one or more broken fingers of the first array of fingers 56A and/or the second array of fingers 56B. In another example, the operational aspects may include a decentralized tool and/or a misaligned tool (e.g., multi-finger caliper tool 52 is offset or off-center relative to a central axis of the multi-finger caliper tool 52). Additionally or alternatively, the interpretation system 50 may apply a model (e.g., a second model) indicative of an elliptical shape to remove outliers from the first set of measurements and/or the second set of measurements. As such, the interpretation system 50 may apply the model to adjust the measurements from the multi-finger caliper tool 52 to generate corrected radii values corresponding to the measurements. For example, the interpretation system 50 may generate a first set of corrected radii values based on the first set of measurements from the first array of fingers 56A and a second set of corrected radii values based on the second set of measurements from the second array of fingers 56B.

Using the corrected radii values, the interpretation system 50 may identify one or more defects within a portion of the wellbore 18. For example, the interpretation system 50 may generate defect maps (e.g., mapping defects relative to an axial position along the central axis of the wellbore 18 and also a circumferential direction about the central axis) based on the corrected radii values. The interpretation system 50 may identify defects within the interior surface of the portion of the wellbore 18 based on image processing techniques and the defect maps. In other instances, the interpretation system 50 may identify the defects based on variations between absolute corrected radii values. The interpretation system 50 may determine a severity of the defect based on a depth (e.g., radial depth) of the defect, a length of the defect, a width of the defect, a position of the defect, or any combination thereof. In certain instances, the interpretation system 50 may identify multiple defects within the portion of the wellbore 18. The interpretation system 50 may group the defects together based on a relative distance between each defect and/or a third model indicative of mechanical and/or stress considerations. The interpretation system 50 may score various defects and groups of defects on a severity scale (e.g., increasing severity from 1 to 10, 1 to 100, etc.). In certain embodiments, a close spacing (e.g., less than a threshold spacing) between multiple defects may increase the score for a group of defects. In some embodiments, a close spacing (e.g., less than a threshold spacing) between one or more defects and a structural feature (e.g., a wellbore connection or flange, a lateral port, a seal, etc.) may increase the score for the one or more defects. The interpretation system 50 may also identify a repetition frequency of each defect across different multi-finger caliper measurements to verify (e.g., validate) the defect. For example, the interpretation system 50 may identify a repetition frequency between the first set of corrected radii values, the second set of corrected radii values, and one or more stored sets of corrected radii values generated by different multi-finger caliper tools 52 that may be stored in the memory 60 and/or storage component 62.

The interpretation system 50 may determine wellbore strength for the portion of the wellbore 18 based on the defects and a model (e.g., third model) indicative of mechanical and/or stress considerations. In certain instances, the model may include industry standards with respect to wellbore strengths, grouping defects, and the like. For example, the interpretation system 50 may determine an amount of pressure the portion of the wellbore 18 with the defects can withstand. The interpretation system 50 may also generate and output the corrosion analysis of the wellbore 18 based on the adjusted radii values and a threshold radius value. For example, the interpretation system 50 may generate and output the corrosion analysis of the portion of the wellbore 18 based on a comparison between the first set of measurements from the first array of fingers 56A to identify a thickness of corrosion on the interior surface of the wellbore 18, a length of the corrosion, a percentage of the corrosion, and so on. For example, the interpretation system 50 may output a summary table with a corrosion level (e.g., state) and/or properties for each collar and joint of the wellbore. The corrosion level may include a percentage of corrosion, a thickness of the corrosion, a length of the corrosion, and so on. The properties may include a minimum inner diameter, a maximum penetration, and so on.

In certain instances, the interpretation system 50 may also identify and merge measurements from different multi-finger caliper tools 52. The measurements may be associated with the portion of the wellbore 18 and generated under different conditions. The interpretation system 50 may align the measurements in depth and/or azimuth, then the interpretation system 50 may merge the measurements to generate a composite measurement with enhanced resolution (e.g., high resolution). The interpretation system 50 may identify defects within the portion of the wellbore 18, wellbore strength, corrosion, and the like based on the composite measurement.

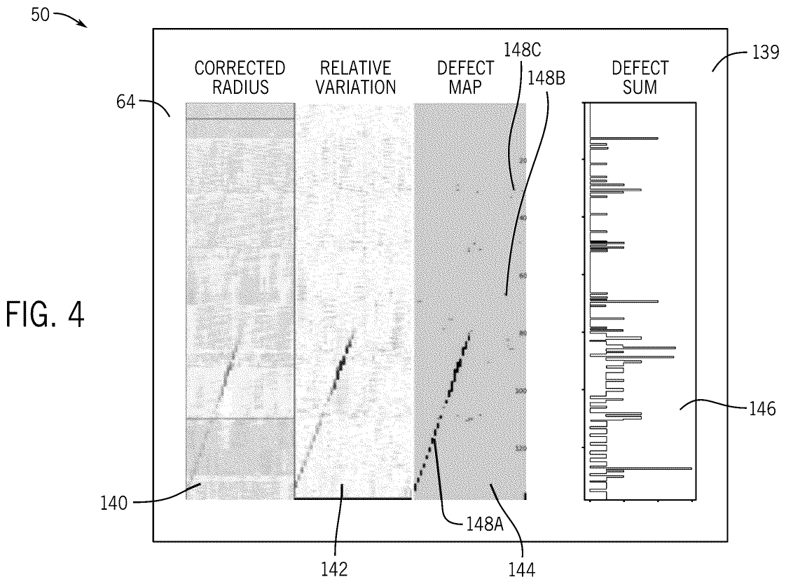

The interpretation system 50 may instruct the display 64 to output the defect maps, the corrosion analysis, the wellbore strength, the repetition index, and the like. For example, the interpretation system 50 may identify and output an interval of interest corresponding to a portion of the wellbore 18 with a corrosion level greater than a threshold corrosion level and/or wellbore strength below a threshold wellbore strength. As illustrated in FIG. 4, the interpretation system 50 may output a visual indication of corrected radii values, relative variations between the corrected radii values, a defect map, and variations in defect numbers along a depth via a graphical user interface (GUI) 139 of an electronic display. The interpretation system 50 may also output one or more buttons prompting for user input. The buttons may include a first button indicative of initiating production operations, a second button indicative of continuing production operations, a third button indicative of adjusting production operations, a fourth button indicative of saving the measurements, and so on.

In certain instances, the interpretation system 50 may instruct operation of one or more components within the hydrocarbon site 10 based on the defect map and/or various properties of the wellbore. For example, the interpretation system 50 may instruct one or more components of the hydrocarbon site 10 to initiate or continue production operations in response to determining the corrosion levels are less than a threshold corrosion level and/or the wellbore strength is greater than a threshold wellbore strength. In another example, the interpretation system 50 may instruct one or more components of the hydrocarbon site 10 to perform a corrective action in response to determining that corrosion levels are greater than the threshold corrosion level and/or the wellbore strength is less than a threshold wellbore strength. For example, the interpretation system 50 may instruct one or more components of the hydrocarbon site 10 to remove or repair a portion of the wellbore 18 as the corrective action. In another example, the interpretation system 50 may instruct one or more components (e.g., welding tool, surface coating tool, patching or plugging tool, etc.) to patch the portion of the wellbore 18 as the corrective action. The corrective actions may also include one removing a portion of the wellbore 18 in response to determining that a severity of the defect is greater than a threshold severity, injecting cement into the portion of the wellbore 18 in response to identifying a leak point, and so on. Still in other examples, the interpretation system 50 may instruct the production operations to stop for a period of time as the corrective action and adjust the tools within the wellbore 18, such as by instructing one or more tools to be positioned the wellbore 18 or to be removed from the wellbore 18. In some embodiments, the interpretation system 50 may directly and/or indirectly control (e.g., via a processor-based controller) one or more valves, pumps, compressors, chemical injection systems, downhole tools, surface tools and equipment, or any combination thereof, based on the defect map and/or various properties of the wellbore.

In certain instances, the interpretation system 50 may implement machine learning techniques and/or artificial intelligence to interpret the measurements and output a predicted analysis. For example, the memory 60 and/or storage component 62 may store a machine learning model that may be trained based on ‘training data’ indicative of different use cases and/or measurements from the multi-finger caliper tool 52. The model may also be trained based on measurements from the multi-finger caliper tool 52 and/or interpretations performed by the interpretation system 50 over time. As such, the interpretation system 50 may implement the machine learning techniques and/or artificial intelligence to adjust the measurements from the multi-finger caliper tool 52 to generate corrected radii values, identify one or more defects based on the corrected radii values, determine a wellbore strength, determine a severity of the defect, determine a corrosion level, identify a collar of the wellbore 18, and so on. In another example, the interpretation system 50 may implement the machine learning techniques and/or artificial intelligence to perform a corrosion analysis of the portion of the wellbore 18 based on the measurements from the multi-finger caliper tool 52. Still in another example, the interpretation system 50 may implement the machine learning techniques and/or artificial intelligence to identify measurements from different multi-finger caliper tools, align the measurements, and generate the composite measurement. In certain embodiments, the interpretation system 50 may analyze measurements from the multi-finger caliper tool 52 taken at a plurality of different times (e.g., days, weeks, months, or years), identify trends in the wellbore 18 (e.g., trends in the defects, structural integrity, etc.), generate predictions for future health and/or failure of the wellbore 18, schedule future maintenance (e.g., repairs, replacements, etc.), and generate control parameters (e.g., changing flow rates or operational characteristics of the wellbore) that may extend the life of the wellbore 18 until maintenance can be performed on the wellbore 18.

Although the illustrated example of FIG. 2 includes one multi-finger caliper tool 52, it may be understood that the interpretation system 50 may be communicatively coupled to more than one multi-finger caliper tool 52 and receive measurements from each multi-finger caliper tool 52 indicative of the interior surface of at least a portion of the wellbore 18.

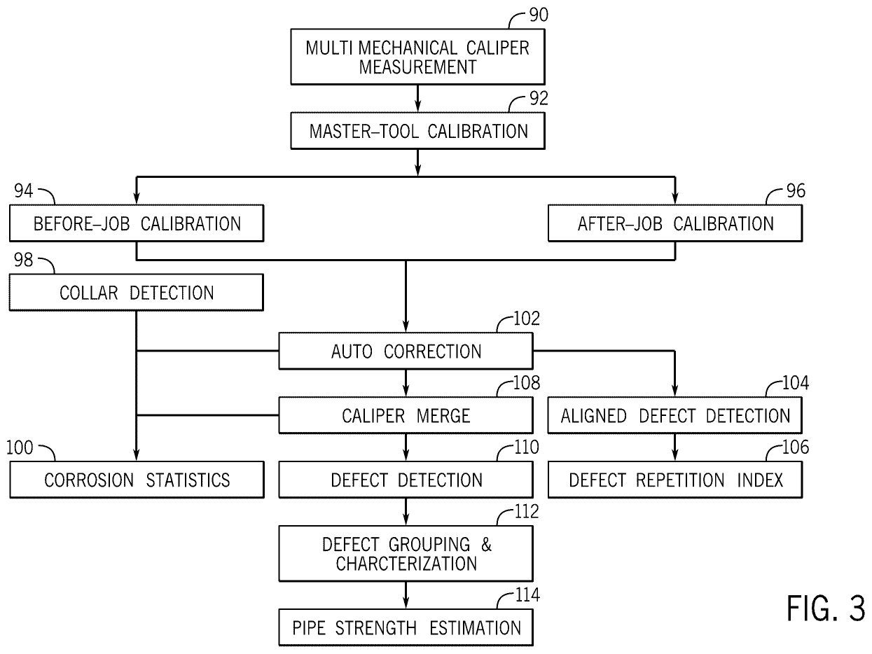

FIG. 3 illustrates a flow diagram of operating the multi-finger caliper tool 52 and interpretating measurements from the multi-finger caliper tool 52 by the interpretation system 50. For example, the interpretation system 50 to may interpret the measurements to generate and/or output a visual (e.g., surface image) indicative of the interior surface of a portion of the wellbore 18, identify one or more defects within the portion of the wellbore 18, identify intervals interest, and so on.

At block 90, the interpretation system 50 may receive measurements from the multi-finger caliper tool 52. For example, the interpretation system 50 may receive a first set of measurements for a portion of the wellbore 18 from the first array of fingers 56A of the multi-finger caliper tool 52 and a second set of measurements from the second array of fingers 56B for the portion of the wellbore 18. Additionally or alternatively, the interpretation system 50 may receive multiple sets of measurements from different multi-finger caliper tools 52 positioned within respective portions of the wellbore 18. As discussed herein, the interpretation system 50 may convert electrical measurements from the multi-finger caliper tool 52 into radii values using at least one model stored in the memory 60 and/or the storage component 62.

The models may be generated during at least one of the following calibration steps: Master-tool Calibration step (block 92), Before-Job Calibration step (block 94), and After-Job Calibration step (block 96). At block 92, the interpretation system 50 may instruct the multi-finger caliper tool 52 to traverse through different pipes of known diameters at various temperatures to calibrate the multi-finger caliper tool 52. The multi-finger caliper tool 52 may generate the electrical measurement, via a linear variable displacement transducer coupled to each finger, by converting a finger opening (e.g., extension) into the electrical measurement. The conversion from displacement to electrical measurement may be performed at various temperatures to account for transducer sensitivity to temperature. The interpretation system 50 may generate at least one model indicative of a relationship between the electrical measurements and different radii values generated during the Master-tool Calibration step. For example, the Master-tool Calibration step (block 92) may occur during manufacturing of the multi-finger caliper tool 52 prior to deployment to a particular site (e.g., hydrocarbon site 10) for measurements.

At block 94, the interpretation system 50 may perform a Before-Job Calibration of the multi-finger caliper tool 52. For example, the interpretation system 50 may instruct the multi-finger caliper tool 52 to traverse through different pipes of known diameters at the surface and/or at ambient temperature to calibrate the multi-finger caliper tool 52 prior to operation of the multi-finger caliper tool 52 within the wellbore 18. In certain embodiments, the Before-Job Calibration of the multi-finger caliper tool 52 may be performed immediately prior to a measurement run in the wellbore 18, such as within the week, days, and/or hours immediately preceding the measurement run. The interpretation system 50 may compare the measurements generated during the Before-Job Calibration step to the measurements from the Master-tool Calibration step to identify variations in electrical measurements. The interpretation system 50 may generate at least one model indicative of the relationship between the electrical measurements and different radii values generated during the Before-Job Calibration step. At least one model may include coefficients generated based on the measurements from the Before-Job Calibration and, if available, the After-Job Calibration. For example, the interpretation system 50 may determine gains and/or offsets to be applied to the measurements and store the variations in the model. The interpretation system 50 may use the model to centralize measurements generated by the multi-finger caliper tool 52 by applying the gains and/or offsets. The model may include a linear regression where the relationship between a corrected measured radius and the known diameters of the different rings is considered an affine function. Additionally or alternatively, the model may include higher order polynomial functions. In certain instances, the interpretation system 50 may adjust the measurements using a fitting method and/or fitting the measurements to the model generated during the Before-Job Calibration step. As such, the interpretation system 50 may correct the measurements for any variations on transducers and/or fingers of the multi-finger caliper tool 52 that may occur between the time of the Master-tool Calibration and the Before-Job Calibration.

At block 96, the interpretation system 50 may perform an After-Job Calibration of the multi-finger caliper tool 52. The interpretation system 50 may instruct the multi-finger caliper tool 52 to traverse through different pipes of known diameters at ambient temperature to calibrate the multi-finger caliper tool 52 after operation of the multi-finger caliper tool 52 within the wellbore 18 in a similar manner as the Before-Job Calibration step. In certain embodiments, the After-Job Calibration of the multi-finger caliper tool 52 may be performed immediately after a measurement run in the wellbore 18, such as within the week, days, and/or hours immediately after the measurement run. The interpretation system 50 may generate at least one model indicative of the relationship between the electrical measurements and different radii values generated during the After-Job Calibration step, a difference between the electrical measurements generated during the After-Job Calibration step and the Before-JobCalibration step, or both. The model may include coefficients generated based on the measurements from the Before-Job Calibration and the After-Job Calibration. Additionally or alternatively, the interpretation system 50 may identify abrasion to one or more fingers of the multi-finger caliper tool 52 that may be induced by rough conditions within the wellbore 18 based on a variations in the measurements from the After-Job Calibration and the measurements from the Before-Job Calibration. The interpretation system 50 may store the identification of fingers with abrasion in the model.

At block 98, the interpretation system 50 may perform a collar detection based on the measurements received at block 90. For example, the interpretation system 50 may identify collars of the wellbore 18 based on changes in diameter within the measurements. The collars may be associated with connections between sections of the wellbore 18, and thus the collars may include annular bodies, flanges, or connecting structures that differ (e.g., diameter change) from the connected sections of the wellbore 18. The collars may be identified based on a diameter greater than a threshold diameter. The threshold diameter may include a diameter of a straight portion of the wellbore 18, while the collars may include the joints of the wellbore 18. The interpretation system 50 may output a table including a state per collar of the measured portion of the wellbore 18. The state may include the diameter of the collar and/or a comparison between the diameter of the collar and the threshold diameter. In certain instances, the interpretation system 50 may combine measurements from the multi-finger caliper tool 52 and one or more tools within the hydrocarbon site 10 to identify the collars.

At block 100, the interpretation system 50 may generate and output corrosion statistics based on measurements received at block 90 and the collar detection at block 98. For example, the interpretation system 50 may determine a corrosion level based on a comparison between the diameter of the wellbore 18 and the threshold diameter. The interpretation system 50 may generate the corrosion statistics based on variations in the measurements and/or the comparison. The interpretation system 50 may output a table with the collars (e.g., wellbore joints) of the wellbore 18 and a corresponding corrosion level. The table may also include statistics indicative of the wellbore 18, such as a minimum inner diameter, a maximum penetration, and so on. The interpretation system 50 may also identify intervals of interest that include one or more collars with a corrosion level greater than a threshold corrosion level. In certain instances, the interpretation system 50 may instruct one or more components of the hydrocarbon site 10 repair the portion of the wellbore 18 corresponding to the intervals of interest. The interpretation system 50 may instruct the multi-finger caliper tool 52 to perform a pass on the interval of interest after repairs. The interpretation system 50 may instruct one or more components of the hydrocarbon site 10 to initiate production operations of the corrosion levels at the interval of interest are less than the corrosion threshold and/or instruct the one or more components to perform additional repairs at the interval of interest in response to the corrosion levels being greater than the corrosion threshold.

At block 102, the interpretation system 50 may adjust the measurements from the multi-finger caliper tool 52 received at block 90 to generate corrected radii values. For example, damaged or malfunctioning fingers of the multi-finger caliper tool 52 may introduce tool limitations, which may result in erroneous measurements. For example, the fingers may include broken sections, bent sections, worn sections (e.g., tips), malfunctioning joints (e.g., pivot joints are not properly rotating the fingers), or any combination thereof. In another example, the multi-finger caliper tool 52 may not be centered relative to a central axis of the wellbore 18, thereby introducing error into the measurements. As such, the interpretation system 50 may apply adjust to the measurements to reduce or eliminate measurement errors introduced by the multi-finger caliper tool 52 or by operation of the multi-finger caliper tool 52. Additionally or alternatively, the interpretation system 50 may convert the electrical measurements into radii values and/or adjust the measurements based on the models generated during the Before-Job Calibration step, and/or the After-Job calibration step. For example, the interpretation system 50 may adjust the measurements apply gain and/or offset values generated during the Before-Job Calibration step and/or adjust measurements generated by one or more fingers with abrasion as determined in the After-Job Calibration step. The interpretation system 50 may also perform the adjustment using the one or more models discussed below.

In certain instances, coefficients may be used to calculate the corrected radii values. During real-time processing of measurements from the multi-finger caliper tool 52, the After-Job Calibration step may not be performed, and the interpretation system 50 may use coefficients from the Before-Job Calibration step to calculate the corrected radii values. During post-job processing, the interpretation system may combine coefficients from the Before-Job Calibration step and the After-Job Calibration step to generate combined coefficients for calculating the corrected radii values.

For example, the interpretation system 50 may input the radii values into a model (e.g., second model) to identify and remove outliers from the radii values. The model may describe finger position with respect to the multi-finger caliper tool 52 position within the wellbore 18. The model may represent the interior bore of the wellbore 18 as an elliptical shape. The elliptical shape may be represented by Equation 1 below.

$$A {x}^{2} + B x y + C {y}^{2} + D x + E y - 1 = 0 \qquad ( Equation 1 )$$

Hence, fitting an ellipse with data points (xᵢ, yᵢ) may be achieved by solving a least-square minimization problem illustrated by Equation 2.

$${min}_{θ} {‖ X θ - 1 ‖}_{2}^{2} \qquad ( Equation 2 )$$

With θ=(A, B, C, D, E) being the vector of second order polynomial coefficient and

$$X = {( {x}_{i}^{2} , {x}_{i} {y}_{i} , {y}_{2}^{2} , {x}_{i} , {y}_{i} )}_{i}$$

as a matrix formed from the data points. To include the presence of possible malfunctioning fingers of the multi-finger caliper tool 52, the model may include extra constraints in the minimization problem and to keep their numbers low but without a predefined value, the model may include an L¹-regularization term illustrated by Equation 3.

$${min}_{θ , δ} {‖ X θ - 1 - δ ‖}_{2}^{2} + λ {‖ δ ‖}_{1} \qquad ( Equation 3 )$$

With δ=(δᵢ) being the biases from the elliptical shape induced by malfunctioning fingers. The biases may be restricted to account for specific cases, such as negative values for non-opened fingers as illustrated by Equation 4.

$${min}_{θ , δ} {‖ X θ - 1 - δ ‖}_{2}^{2} + λ {‖ δ ‖}_{1} \qquad ( Equation 4 )$$

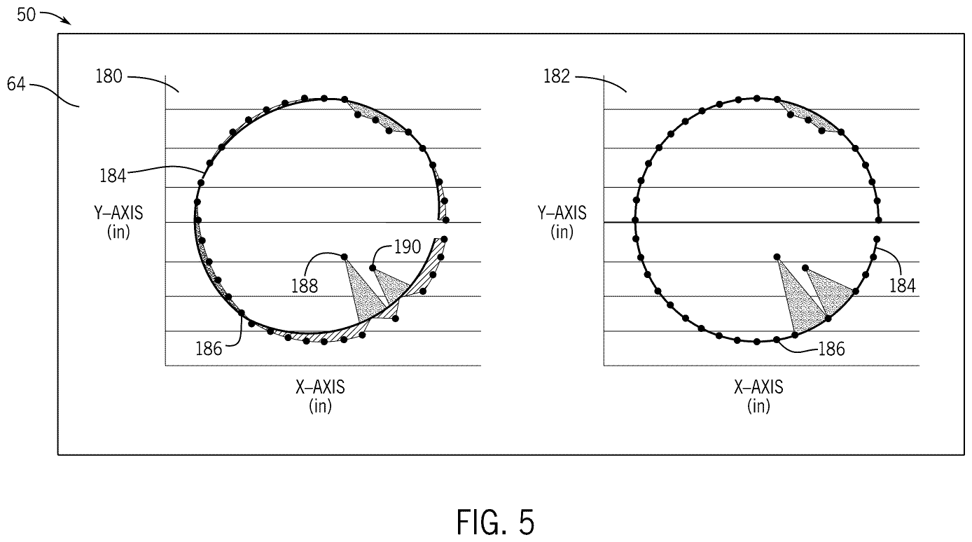

The model may include biases as a solution to the minimization problem, where the biases may be given real numbers. The model may include a robust statistical method to flag (binarization step) and produce a list of malfunctioning fingers. The model may exclude measurements from the malfunctioning fingers from further computations. As such, the interpretation system 50 may identify outliers in the radii values resulting from broken and/or malfunctioning fingers of the multi-finger caliper tool 52 based on the model described in Equations 1-4. The interpretation system 50 may exclude the outliers (e.g., radius variations) from the corrected radii values and/or the interpretation, as further described with respect to FIG. 5. As such, the interpretation system 50 may generate corrected radii values based on the measurements from block 90 and/or the models from the Master-tool Calibration step, the Before-Job Calibration step, the After-Job Calibration step, the elliptical model, or any combination thereof.

In other instances, the interpretation system 50 may adjust the radii values based on variations in the corrected radii values. For example, the interpretation system 50 may perform a Finger Offset Correction, which adjusts for deviations between an average value of each azimuth and an overall average of all azimuth measurements. As used herein, the “azimuth measurement” may include measurements in the circumferential direction about the central axis of the wellbore 18. For example, the interpretation system 50 may subtract an average radius value of all azimuths from the radius value of each azimuth. As such, the interpretation system 50 may generate relative radius variation data, as illustrated in FIG. 4, which may highlight defects. In another example, interpretation system 50 may automatically generate individual defect maps for different multi-finger caliper tools 52, as illustrated in FIG. 4, based on the relative radius variation data. Based on the defect detection map, the interpretation system 50 may compute a total number and strength of defect pixels at each depth. As such, the interpretation system 50 provides a quantitative tool to evaluate the quality of each depth to be included in finger offset estimations. Based on the defect variation along the depth image, the interpretation system 50 may automatically identify a depth interval for estimating finger offset deviations. In a selected depth, the interpretation system 50 may ignore defect points during finger offset deviation computation and only use non-defect points to estimate the finger offset deviation for each azimuth.

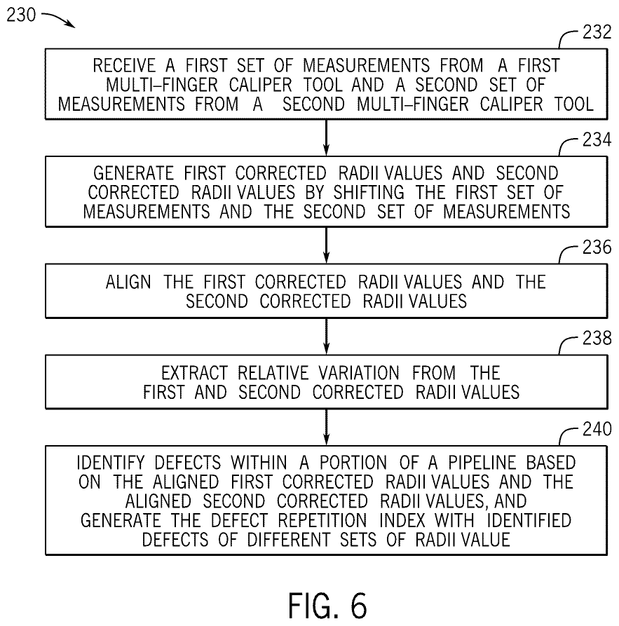

At block 104, the interpretation system 50 may perform an aligned defect detection based on the steps illustrated in FIG. 6. For example, the interpretation system 50 aligns the first set of measurements from the first array of fingers 56A and the second set of measurements from the second array of fingers 56B based on depth, radius, and/or azimuth. Additionally or alternatively, the interpretation system 50 may receive an additional set of measurements from a different multi-finger caliper tool 52 indicative of the portion of the wellbore 18 and align the first set of measurements or the second set of measurements with the additional set of measurements based on depth, radius, and/or azimuth. The interpretation system 50 may use the aligned measurements to detect defects within the portion of the wellbore 18.

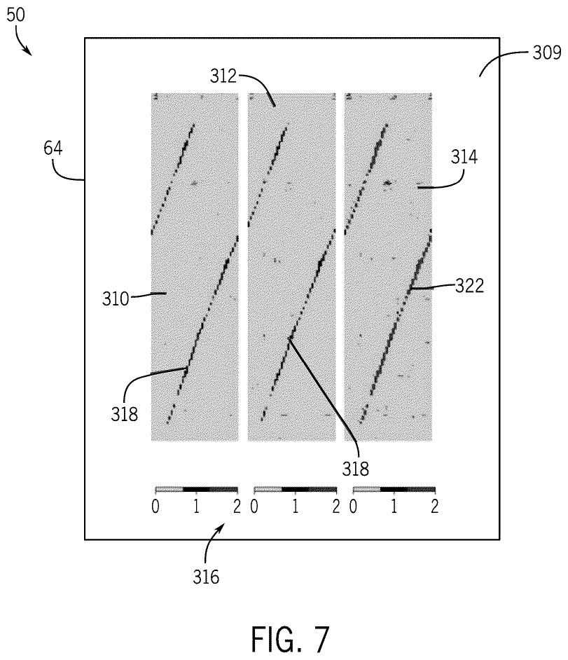

At block 106, the interpretation system 50 may identify a repetition frequency of each defect across multiple measurements from different multi-finger caliper tools 52 based on extracted defects, as illustrated by FIGS. 6 and 7. For example, the interpretation system 50 may identify a defect within the first set of measurements and may verify the defect within the second set of measurements. In another example, the interpretation system 50 may identify the defect within the first set of measurements and/or the second set of measurements and verify the measurement within the additional set of measurements. If the interpretation system 50 identifies the defect within the second set of measurements and/or the additional set of measurements, the interpretation system 50 may verify the defect. The repetition of defects in different sets of measurements may be an indicator for measurement reliability. The process for defect detection and defect repetition index is further described with respect to FIGS. 6 and 7. If the interpretation system 50 does not identify the defect within the second set of measurements and/or the additional set of measurements, the interpretation system 50 may instruct a different multi-finger caliper tool 52 to perform a pass through the portion of the wellbore 18 corresponding to the defect and generate measurements. The interpretation system 50 may use the measurements to verify the defect.

At block 108, the interpretation system 50 may perform a caliper merge step to generate a composite measurement indicative of the portion of the wellbore 18. For example, the interpretation system 50 may retrieve multiple multi-finger caliper tool measurements indicative of the same portion of the wellbore 18 and generated (e.g., taken) under different conditions (e.g., temperature). For example, the interpretation system 50 may align the multiple multi-finger caliper tool measurements in depth and in azimuth. The interpretation system 50 may then merge (e.g., combine) the measurements to generate a composite measurement (e.g., an aggregated representation) indicative of the portion of the wellbore 18, which may provide higher resolution measurements and/or reduce or eliminate impact of outliers and/or erroneous measurements. For example, the interpretation system 50 may retrieve two multi-finger caliper tool measurements that may be generated by a multi-finger caliper tool 52 with 40 fingers at different times and merge two multi-finger caliper tool measurements to generate a composite image with an 80 finger resolution. As such, the composite measurement may provide higher resolution measurements (e.g., a higher resolution image) in comparison to the individual multi-finger caliper tool measurements. To generate the composite measurement, the interpretation system 50 may average multiple values at one pixel value into a single representative value and/or use a weighted average.

At block 110, the interpretation system 50 may identify defects within the composite measurement. For example, the interpretation system 50 may identify the defects by detecting variations in the absolute radii values by extracting relative variations from absolute radius data of the composite multi-finger caliper measurement by applying defect detection methods.

At block 112, the interpretation system 50 may group together the one or more defects and characterize the one or more defects. When several defects are detected, their contribution to decreasing wellbore strength varies based on their relative distance from one another. The interpretation system 50 may group the defects based on a model (e.g., third model) indicative of mechanical on stress interaction considerations. The model may be based on industry standards.

At block 114, the interpretation system 50 may estimate the strength of the portion of the wellbore 18 based on the defects identified in blocks 110 and 112. For example, the interpretation system 50 may output pre-defined tables, finite element analysis, a 3D description of the wellbore, and so on. The interpretation system 50 may also determine a severity of the defect based on a geometry of the defect (e.g., a depth of the defect, a length of the defect, a shape of the defect, a volume of the defect, etc.), a position of the defect, and so on. The severity of the defect also may be at least partially based on a material used for the wellbore 18, a diameter of the wellbore 18, a wall thickness of the wellbore 18, an age of the wellbore 18, normal operating conditions (e.g., pressure, flowrate, fluid composition, etc.) in the wellbore 18, or any combination thereof. If the severity of the defect is greater than a threshold severity, the interpretation system 50 may instruct and/or control one or more tools (e.g., welding tool, patching tool, coating tool, cementing tool, etc.) to repair the portion of the wellbore 18 with the defect. The interpretation system 50 may instruct one or more components of the hydrocarbon site 10 to stop production operations and/or delay production operations until the portion of the wellbore 18 may be repaired. If the severity of the defect is less than the threshold severity, the interpretation system 50 may instruct one or more components of the hydrocarbon site 10 to initiate production operations.

FIG. 4 illustrates a graphical user interface (GUI) 139 presenting generated outputs of the interpretation system of FIG. 2. The GUI includes a first graph 140 indicative of corrected radius, a second graph 142 indicative of relative variations in the corrected radius, a third graph 144 indicative of a defect map, and a fourth graph 146 indicative of a number of defects.

The first graph 140 is a visual indication of corrected radii values of a portion of the wellbore 18. The first graph 140 may illustrate variations in the interior surface of the portion of the wellbore 18 as a function of image intensity (e.g., a function of grayscale or a function of color). The horizontal axis of the first graph 140 represents the circumferential direction or azimuthal direction about the central axis of the wellbore 18, whereas the vertical axis of the first graph 140 represents the axial direction along the central axis of the wellbore 18. The image intensity (e.g., grayscale or color) may indicate relative changes (e.g., variations) in radii, indicate relative highs and lows (e.g., peaks and valleys) within the interior surface, and so on. As such, the interpretation system 50 may provide visual indication of the interior portion of the portion of the wellbore. Additionally or alternatively, the interpretation system 50 may use the corrected radii values to perform a collar detection step (block 98) and/or determine corrosion levels within the portion of the wellbore 18.

The second graph 142 illustrates relative variation of the corrected radii values as a function of image intensity (e.g., a function of grayscale or a function of color). Similar to the first graph 140, the horizontal axis of the second graph 142 represents the circumferential direction or azimuthal direction about the central axis of the wellbore 18, whereas the vertical axis of the second graph 142 represents the axial direction along the central axis of the wellbore 18. For example, the interpretation system 50 may generate the relative variation by subtracting the average radius value of all azimuths from the radius value of each azimuth. As such, a difference between each radius value and the average radius value may be determined and displayed. The differences may be displayed on the second graph 142 with respective image intensity (e.g., grayscale or color). In certain instances, a larger difference may provide a better indication of a defect in comparison to a smaller difference.

The third graph 144 illustrates multiple defects 148 within the portion of the wellbore 18 as a function of image intensity (e.g., a function of grayscale or a function of color). Similar to the first graph 140, the horizontal axis of the third graph 144 represents the circumferential direction or azimuthal direction about the central axis of the wellbore 18, whereas the vertical axis of the third graph 144 represents the axial direction along the central axis of the wellbore 18. The interpretation system 50 may identify areas with significant changes in depth, single point variations relative to a surrounding background, and the like in the third graph 144. For example, a first defect 148A may include a defect caused by an axial tool scratching or gouging the interior surface of the wellbore 18, a second defect 148B may include a single-point defect caused by corrosion, and/or a third defect 148C may include the single-point defect. As illustrated, the first defect 148A generally extends in an axial direction along a central axis of the wellbore 18, but the first defect 148A also turns or angles due to rotational movement of the tool in the wellbore while moving the axial direction. The variations in depth within the third graph 144 may be represented as a function of image intensity (e.g., grayscale or color). For example, an area with variations in depth may be represented by a first image intensity (e.g., grayscale or color) and an area without variations in depth may be represented by a second image intensity (e.g., grayscale or color). As illustrated, the first defect 148A, the second defect 148B, and/or the third defect 148C are illustrated by a first image intensity (e.g., grayscale or color) while the surrounding background is illustrated by a second image intensity (e.g., grayscale or color). The interpretation system 50 may use image processing techniques to identify the first defect 148A, the second defect 148B, and/or the third defect 148C in the third graph 144. Additionally or alternatively, the interpretation system 50 may identify the defects based on areas with significant variations in depth, single-point variations relative to a surrounding background, and the like in the third graph 144. The interpretation system 50 may also determine a severity of the defect 148 by determining a length of the defect 148, a width of the defect 148, a depth of the defect 148, and so on.

The fourth graph 146 illustrates a variation in defect numbers versus depth. The fourth graph 146 illustrates a number of defects (horizontal axis) over an axial length (e.g., vertical axis) of the portion of the wellbore 18. For example, if the wellbore 18 represents a wellbore (e.g., casing, tubing, liner, etc.), then the fourth graph 146 illustrates the number of defects on the horizontal axis as a function of the depth on the vertical axis. The interpretation system 50 may generate the fourth graph 146 by determining the total number and strength of defect pixels at each depth based on the third graph 144. As such, the interpretation system 50 may provide a quantitative tool to evaluate the quality of each depth for finger offset estimations (e.g., Finger Offset Correction). Based on the defect variation, the interpretation system 50 may automatically identify a depth interval for estimating finger offset deviation.

FIG. 5 illustrates a first elliptical model 180 and second elliptical model 182 that may be used by the interpretation system 50 to determine various properties of the wellbore 18, in accordance with embodiments of the present disclosure. The interpretation system 50 may adjust the radii values based on a model indicative of an elliptical shape of an interior bore of the wellbore 18. Although an ideal geometry of the interior bore may be a circular or cylindrical geometry, the interior bore of the wellbore 18 may be elliptical in shape due to manufacturing defects, forces applied on the wellbore 18, or other factors. Accordingly, by modelling the interior bore of the wellbore 18 as an elliptical shape, the interpretation system 50 can more accurately identify defects (e.g., protrusions, grooves, cracks, holes, corrosion, etc.) in the interior bore of the wellbore 18. For example, the interpretation system 50 may center and/or fit the radii values to a model indicative of an elliptical shape in order to determine a center of the multi-finger caliper tool 52 relative the position of the multi-finger caliper tool 52 within the wellbore 18.

With the foregoing in mind, the first elliptical model 180 illustrates fitting the radii values to a standard ellipse shape and the second elliptical model 182 illustrates fitting the radii values to an improved ellipse shape. As illustrated, the lines 184 illustrate a fitted shape of a respective elliptical models 180 and 182 and the dots 186 illustrate the radii values (e.g., measured points) from the multi-finger caliper tool 52. The fitted shape may include an estimated wellbore diameter. For example, each dot 186 may represent a radii value measured by a respective finger of the multi-finger caliper tool 52.

The radii values may not fit to the first elliptical model 180. As illustrated, the radii values may extend past the fitted shape of the first elliptical model 180, which may be due to misplacement of a finger, an error by the linear variable displacement transducer, and/or other tool limitations. Additionally, as illustrated, two of the fingers of the multi-finger caliper tool 52 may generate abnormal measurements illustrated by dots 188 and 190. The abnormal measurements may bias the fitted measurements to the abnormal values, which introduces errors into the corrected radii values.

As illustrated by the second elliptical model 182, the residuals of shape fitting to radii values may extend to defect errors within the radii values. For example, the second elliptical model 182 may utilize thresholding (e.g., filtering) to detect radii values greater than a threshold radius value (e.g., nominal radius, ovalized radius). The second elliptical model 182 may remove the detected radii values from the fitted measurement, which may reduce or eliminate error introduced by tool limitations. The second elliptical model 182 may also utilize geometrical distance errors as applied to a circle or an ellipse shape and a combination of robust loss functions for a least squares fitting method to reduce or eliminate errors. Additionally or alternatively, the interpretation system 50 may perform a comparison of multiple independent fittings to the second elliptical model 182 to generate a bad finger probability map. Using the bad finger probability map, the interpretation system 50 may identify broken and/or malfunctioning fingers of the multi-finger caliper tool as the likelihood of repeating erroneous radii values between images is low.

FIG. 6 illustrates a flowchart of an example method 230 for aligning measurements from the multi-finger caliper tool 52 and identifying defects and/or a repetition frequency of the defects based on the measurements by the interpretation system 50. The interpretation system 50 may evaluate defect repetition by comparing measurements from different multi-finger caliper tools 52. The repetition of defects across measurements may indicate measurement reliability and verify the defect.

At block 232, the interpretation system 50 may receive a first set of measurements from a first multi-finger caliper tool 52 and second set of measurements from a second multi-finger caliper tool 52.

At block 234, the interpretation system 50 may generate first corrected radii values and second corrected radii values based on the first set of measurements and the second set of radii values. To this end, the interpretation system 50 may adjust the first set of measurements and the second set of measurements based on the Auto correction step discussed with respect to FIG. 3, block 102. In another example, the interpretation system 50 may perform a Finger Offset Correction to generate the corrected radii values.

At block 236, the interpretation system 50 may generate aligned first corrected radii values and aligned second corrected radii values by shifting the first corrected radii values and the second corrected radii values. The interpretation system 50 may adjust the first corrected radii values and/or the second corrected radii values using a depth shift, a radius shift, and/or an azimuth shift to adjust for discrepancies between multi-finger caliper tools 52. For example, the first corrected radii values may be shifted in radius, depth, and/or azimuth to align with the second corrected radii values. In another example, the second corrected radii values may be shifted in radius, depth, and/or azimuth to align with the first corrected radii values. As such, radii values from different multi-finger caliper tools may be compared. Furthermore, the interpretation system 50 may reduce or eliminate measurement errors caused by operational factors and/or tool differences

At block 238, the interpretation system 50 may extract relative variation from the first corrected radii values and the second corrected radii values. The interpretation system 50 may convert the aligned first corrected radii values and/or the aligned second corrected radii values into a format that highlights defects. For example, the interpretation system 50 may remove a local background to highlight relative variations between the aligned first corrected radii values and/or the aligned second corrected radii values. The interpretation system 50 may identify relative variations in the aligned first corrected radii values and the aligned second corrected radii values, as illustrated in FIG. 4. In another example, the interpretation system 50 may identify outliers and/or exclude radius variations by fitting the aligned first corrected radii values and/or the aligned second corrected radii values to a model (e.g., the second model, the second elliptical model 182).

At block 240, the interpretation system 50 may identify defects within a portion of a wellbore 18 based on the aligned first corrected radii values and the aligned second corrected radii values. For example, the interpretation system 50 may automatically identify relative radius variation data based on the aligned first corrected radii values and the aligned second corrected radii values and identify the defects based on the radius variation data. In another example, the interpretation system 50 may generate individual defect maps based on the aligned first corrected radii values and the aligned second corrected radii values, as illustrated in FIG. 7. The interpretation system 50 may determine a repetition of the defects after identifying the defects. In other words, the interpretation system 50 may generate a first defect map based on measurements from the first multi-finger caliper tool 52 and a second defect map based on measurements from the second multi-finger caliper tool 52. The interpretation system 50 may identify defects based on the defect maps by detecting single-point variations relative to a surrounding background or using image processing techniques. Additionally or alternatively, the interpretation system 50 may match defect overlaps between different multi-finger caliper tools by checking each spatial position (e.g., depth, azimuth) of the defect maps within a pre-determined distance tolerance.

The method 230 will be described as being performed by the interpretation system 50, but it should be noted that any suitable processor-based device may be specially programmed to perform any of the steps of the method described herein. It should be understood that the steps of the method 230 may not be performed in the specific order shown illustrated. Furthermore, it should be understood that the method 230 described below may include some or all the steps illustrated in FIG. 6. For example, the interpretation system 50 may output a GUI on an electronic display indicative of the defects, the first corrected radii values, the second corrected radii values, the aligned first corrected radii values, the aligned second corrected radii values, or any combination thereof. In another example, the interpretation system 50 may instruct one or more components of the hydrocarbon site 10 to perform an action based on the identified defect. As such, the interpretation system 50 may adjust production operations based on the identified defect.

FIG. 7 illustrates a GUI 309 presenting generated outputs of the interpretation system 50. The GUI 309 includes a first defect map 310, a second defect map 312, and a defect repetition map 314. The horizontal axis of the first and second defect maps 310, 312, and the defect repetition map 314 represents the circumferential direction or azimuthal direction about the central axis of the wellbore 18, whereas the vertical axis of the first and second defect maps 310, 312, and the defect repetition map 314 represents the axial direction (e.g., depth) along the central axis of the wellbore 18. As discussed herein, the interpretation system 50 may generate the first defect map 310 based on measurements from the first multi-finger caliper tool 52, and the second defect map 312 based on measurements from the second multi-finger caliper tool 52. The first defect map 310 and/or the second defect map 312 may illustrate multiple defects 318 similar to the third graph 144 described with respect to FIG. 4.

The interpretation system 50 may generate the defect repetition map 314 based on the first defect map 310 and the second defect map 312. The defect repetition map 314 may illustrate a repetition frequency associated with each defect. The GUI 309 may include a legend 316 indicative of a repetition number as a function of image intensity (e.g., a function of grayscale or a function of color). For example, if a defect is identified in N-number of defect maps, the interpretation system 50 may set the repetition index for that defect to N. As illustrated, the defect 318 may be identified in two different defect maps 310 and 312. As such, the defect repetition map 314 may illustrate the defect 318 in an image intensity (e.g., grayscale or color) corresponding to N=2.

Technical effects of the disclosed embodiments include interpretating measurements from one or more multi-finger caliper tools to determine various parameters associated with production operations of a well in a hydrocarbon site. For example, the disclosed embodiments may receive measurements from one or more multi-finger caliper tools that may include erroneous measurements introduced by tool limitations and/or operational aspects. The disclosed embodiments may adjust the measurements based on one or more models (e.g., computer models), align measurements from different multi-finger caliper tools, and the like to generate corrected radii values. The disclosed embodiments may identify one or more defects within the wellbore based on the corrected radii values. If multiple defects are identified, the disclosed embodiments may group and characterize the defects based on a model (e.g., computer model) indicative of industry standards and determine a wellbore strength based on the grouped defects. If the wellbore strength is below a threshold wellbore strength, the disclosed embodiments may stop and/or delay production operations within the hydrocarbon site and instruction one or more components to operate (e.g., repair) on a portion of the wellbore associated with the defect. If the wellbore strength is greater than the threshold wellbore strength, the disclosed embodiments may instruct one or more components to initiate or maintain production operations. In certain instances, the disclosed embodiments may receive multiple measurements from different multi-finger caliper tools and identify a repetition frequency of the defect across each of the measurements. In other instances, the disclosed embodiments may merge the measurements to generate a composite measurement with improved resolution in comparison to a single measurement. Additionally or alternatively, the disclosed embodiments may use the measurements to identify collars within the wellbore and determine corrosion level of the wellbore. If corrosion levels are greater than a threshold corrosion level, the disclosed embodiments may instruct one or more components to operate on a portion of the wellbore associated with the defect. If the corrosion levels are less than the threshold corrosion level, the disclosed embodiments may instruct the one or more components to initiate or maintain production operations. As such, the disclosed embodiments may improve production operations by improving determination of various properties of the wellbore.

The subject matter described in detail above may be defined by one or more clauses, as set forth below.

In an embodiment, a system may include a multi-finger caliper tool configured to be positioned within a wellbore (e.g., casing, tubing, and/or liner of the wellbore) of a hydrocarbon site, wherein the multi-finger caliper tool configured to generate measurements indicative of an interior surface of the wellbore, a component coupled to the multi-finger caliper tool and configured to adjust a position of the multi-finger caliper tool within the wellbore, and a computing system communicatively coupled to the multi-finger caliper tool. The computing system may include processing circuitry and memory storing instructions. The instructions, when executed by the processing circuitry, may cause the processing circuitry to perform an autonomous workflow to instruct the component to adjust the position of the multi-finger caliper tool within the wellbore to generate the measurements, convert the measurements into radii values based on at least one model of a plurality of models, and generate corrected radii values based on the radii values and a second model of the plurality of models. The instructions when executed by the processing circuitry, may also cause the processing circuitry to generate a defect map indicative of a portion of the wellbore based on the corrected radii values and instruct a display to display the defect map.

The system of the preceding clause, wherein the instructions, when executed by the processing circuitry, cause the processing circuitry to identify one or more defects of the portion of the wellbore based on the defect map, group the one or more defects based on a third model of the plurality of models, and determine a wellbore strength of the portion of the wellbore based on the one or more defects.

The system of any preceding clause, wherein the instructions, when executed by the processing circuitry, cause the processing circuitry to instruct one or more tools to operate on the portion of the wellbore in response to determining the wellbore strength is less than a threshold wellbore strength.

The system of any preceding clause, wherein the instructions, when executed by the processing circuitry, cause the processing circuitry to instruct the multi-finger caliper tool to generate additional measurements by traversing through the portion of the wellbore corresponding to the one or more defects.

The system of the preceding clause, wherein the instructions, when executed by the processing circuitry, cause the processing circuitry to convert the additional measurements into additional radii values based on the at least one model, generate additional corrected radii values based on the additional radii values and the second model, generate an additional defect map indicative of the portion of the wellbore based on the additional corrected radii values, generate a defect repetition map based on a comparison between the defect map and the additional defect map, and instruct the display to display the defect map, the additional defect map, and the defect repetition map.

The system of the preceding clause, wherein the instructions, when executed by the processing circuitry, cause the processing circuitry to identify one or more additional defects based on the additional corrected radii values and determine a repetition frequency of the one or more defects based on a comparison between the one or more defects and the one or more additional defects, wherein the defect repetition map includes an indication of the repetition frequency.

The system of any preceding clause, wherein the instructions, when executed by the processing circuitry, cause the processing circuitry to generate the at least one model by generating a first model of the at least one model indicative of a first relationship between electrical measurements and respective diameters at various temperatures by instructing the component to adjust a second position of the multi-finger caliper tool within one or more pipes with known diameters, generating a second model of the at least one model indicative of a second relationship between the electrical measurements and respective diameters at ambient temperature by instructing the component to adjust a third position of the multi-finger caliper tool within the one or more pipes with known diameters prior to generating the measurements, and generating a third model of the at least one model indicative of a third relationship between the electrical measurements and respective diameters at the ambient temperature by instructing the component to adjust a fourth position of the multi-finger caliper tool within the one or more pipes with known diameters after generating the measurements.

The system of the preceding clause, wherein the instructions, when executed by the processing circuitry, cause the processing circuitry to generate the corrected radii values by fitting the radii values to the elliptical model, removing outliers from the radii values based on the fitting, and identifying one or more malfunctioning fingers of the multi-finger caliper tool based on the outliers.

In an embodiment, a method may include by processing circuitry, a multi-finger caliper tool to traverse through a wellbore of a hydrocarbon well site, instructing, a component of a hydrocarbon well site to adjust a position of a multi-finger caliper tool within a wellbore of a hydrocarbon well site to generate a set of measurements, receiving a set of measurements indicative of an interior surface of a portion of the wellbore from the multi-finger caliper tool, and converting the set of measurements into a set of radii values based on at least one model of a plurality of models. The method may also include generating, via the processing circuitry, a set of corrected radii values based on the set of radii values and a second model of the plurality of models and generating, via the processing circuitry, a defect map indicative of the portion of the wellbore based on the set of corrected radii values. The method may also include identifying, via the processing circuitry, one or more defects within the portion of the wellbore based on the defect map and instructing, via the processing circuitry, a display to display a graph including the set of corrected radii values and the defect map.

The method of the preceding clause, including instructing, via the processing circuitry, the component to adjust the position of the multi-finger caliper tool through pipes with known diameters at an ambient temperature to generate a first set of calibration data, instructing, via the processing circuitry, the component to adjust the position of the multi-finger caliper tool through the pipes with known diameters at the ambient temperature to generate a second set of calibration data, instructing, via the processing circuitry, the multi-finger caliper tool to generate a second set of calibration data by traversing through the pipes with known diameters at the ambient temperature, determining, via the processing circuitry, a plurality of gains and offsets based on a comparison between the first set of calibration data and stored calibration data and a comparison between the second set of calibration data and the stored calibration data, and applying, via the processing circuitry, the plurality of gains and offsets after converting the set of measurements into the set of radii values.

The method of any preceding clause, including receiving, via the processing circuitry, a second set of measurements indicative of the interior surface of the portion of the wellbore from a second multi-finger caliper tool, wherein the second multi-finger caliper tool is controlled by the component, converting, via the processing circuitry, the second set of measurements into a second set of radii values based on the at least one model, generating, via the processing circuitry, a second set of corrected radii values based on the second set of radii values and the second model, and aligning, via the processing circuitry, the set of corrected radii values and the second set of corrected radii values in depth, radius, azimuth, or any combination thereof.

The method of the preceding clause, including identifying, via the processing circuitry, variations in the second set of corrected radii values, identifying, via the processing circuitry, one or more additional defects based on the variations, and verifying, via the processing circuitry, a first defect of the one or more defects based on the one or more additional defects.

The method of the preceding clause, including incrementing, via the processing circuitry, a defect frequency of the first defect in response to the verification and generating, via the processing circuitry, a defect repetition map including an indication of the defect frequency of the first defect.

The method of any preceding clause, including determining, via the processing circuitry, a wellbore strength of the portion of the wellbore based on grouping the one or more defects and a third model of the plurality of models and instructing, via the processing circuitry, one or more tools to operate on the portion of the wellbore in response to determining the wellbore strength is less than a threshold wellbore strength.

In an embodiment, a system may include a multi-finger caliper tool configured to be positioned within a wellbore of a hydrocarbon site, wherein the multi-finger caliper tool configured to generate measurements indicative of an interior surface of the wellbore, a component coupled to the multi-finger caliper tool and configured to adjust a position of the multi-finger caliper tool, and a computing system communicatively coupled to the multi-finger caliper tool. The computing system may include processing circuitry and memory storing instructions. The instructions, when executed by the processing circuitry may cause the processing circuitry to perform an autonomous workflow to perform a first calibration of the multi-finger caliper tool by instructing the component to adjust the position of the multi-finger caliper tool through one or more pipes with known diameters to generate first calibration measurements while traversing through the one or more pipes, instruct the component to adjust the position of the multi-finger caliper tool within the wellbore to generate the measurements while traversing through the wellbore, and perform a second calibration of the multi-finger caliper tool by instructing the component to adjust the position of the multi-finger caliper tool through the one or more pipes with known diameters to generate second calibration measurements while traversing through the one or more pipes. The instructions, when executed by the processing circuitry may cause the processing circuitry to convert the measurements into radii values based on the first calibration measurements, the second calibration measurements, and at least one model of a plurality of models, generate corrected radii values based on a second model of the plurality of models, generate a defect map indicative of a portion of the wellbore based on the corrected radii values, and instruct a display to display the defect map.

The system of the preceding embodiment, wherein the instructions, when executed by the processing circuitry, cause the processing circuitry to identify a position of a collar within the wellbore based on the measurements, identify a subset of measurements associated with a straight portion of the wellbore based on the position of the collar, convert the subset of measurements into a subset of radii values based on the at least one model, determine a corrosion level of the straight portion of the wellbore based on a comparison between the subset of radii values and a threshold radius value, and instruct the display to display the corrosion level.

The system of the preceding embodiment, wherein the instructions, when executed by the processing circuitry, cause the processing circuitry to instruct one or more tools to operate on the portion of the wellbore in response to determining that the corrosion level is greater than a threshold corrosion threshold.

The system of any preceding embodiment, wherein the instructions, when executed by the processing circuitry, cause the processing circuitry to retrieve one or more additional measurements indicative of the interior surface of the wellbore from a database, generate a composite measurement indicative of the interior surface of the wellbore by merging the one or more additional measurements and the measurements, and identify one or more defects of the interior surface of the wellbore based on the composite measurement.

The system of any preceding embodiment, wherein the instructions, when executed by the processing circuitry, cause the processing circuitry to group the one or more defects based on a relative distance between each defect of the one or more defects, determine a wellbore strength based on grouping the one or more defects and a third model, and instruct one or more tools to operate on the portion of the wellbore in response to determining that the wellbore strength is less than a threshold wellbore strength.

The foregoing description, for purpose of explanation, has been described with reference to specific embodiments. However, the illustrative discussions above are not intended to be exhaustive or to limit the disclosure to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principals of the disclosure and its practical applications, to thereby enable others skilled in the art to best utilize the disclosure and various embodiments with various modifications as are suited to the particular use contemplated.

Finally, the techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A system comprising:
a multi-finger caliper tool configured to be positioned within a wellbore of a hydrocarbon site, wherein the multi-finger caliper tool configured to generate measurements indicative of an interior surface of the wellbore;
a component coupled to the multi-finger caliper tool and configured to adjust a position of the multi-finger caliper tool within the wellbore; and
a computing system communicatively coupled to the multi-finger caliper tool, the computing system comprising:
processing circuitry; and
memory storing instructions, wherein the instructions, when executed by the processing circuitry, cause the processing circuitry to perform an autonomous workflow to:
instruct the component to adjust the position of the multi-finger caliper tool within the wellbore to generate the measurements;
convert the measurements into radii values based on at least one model of a plurality of models;
generate corrected radii values based on the radii values and a second model of the plurality of models;
generate a defect map indicative of a portion of the wellbore based on the corrected radii values; and
instruct a display to display the defect map.

2. The system of claim 1, wherein the instructions, when executed by the processing circuitry, cause the processing circuitry to:
identify one or more defects of the portion of the wellbore based on the defect map;
group the one or more defects based on a third model of the plurality of models; and
determine a wellbore strength of the portion of the wellbore based on the one or more defects.

3. The system of claim 2, wherein the instructions, when executed by the processing circuitry, cause the processing circuitry to:
instruct one or more tools to operate on the portion of the wellbore in response to determining the wellbore strength is less than a threshold wellbore strength.

4. The system of claim 2, wherein the instructions, when executed by the processing circuitry, cause the processing circuitry to:
instruct the multi-finger caliper tool to generate additional measurements by traversing through the portion of the wellbore corresponding to the one or more defects.

5. The system of claim 4, wherein the instructions, when executed by the processing circuitry, cause the processing circuitry to:
convert the additional measurements into additional radii values based on the at least one model;
generate additional corrected radii values based on the additional radii values and the second model;
generate an additional defect map indicative of the portion of the wellbore based on the additional corrected radii values;
generate a defect repetition map based on a comparison between the defect map and the additional defect map; and
instruct the display to display the defect map, the additional defect map, and the defect repetition map.

6. The system of claim 5, wherein the instructions, when executed by the processing circuitry, cause the processing circuitry to:
identify one or more additional defects based on the additional corrected radii values; and
determine a repetition frequency of the one or more defects based on a comparison between the one or more defects and the one or more additional defects, wherein the defect repetition map includes an indication of the repetition frequency.

7. The system of claim 1, wherein the instructions, when executed by the processing circuitry, cause the processing circuitry to generate the at least one model by:
generating a first model of the at least one model indicative of a first relationship between electrical measurements and respective diameters at various temperatures by instructing the component to adjust a second position of the multi-finger caliper tool within one or more pipes with known diameters;
generating a second model of the at least one model indicative of a second relationship between the electrical measurements and respective diameters at ambient temperature by instructing the component to adjust a third position of the multi-finger caliper tool within the one or more pipes with known diameters prior to generating the measurements; and
generating a third model of the at least one model indicative of a third relationship between the electrical measurements and respective diameters at the ambient temperature by instructing the component to adjust a fourth position of the multi-finger caliper tool within the one or more pipes with known diameters after generating the measurements.

8. The system of claim 7, wherein the instructions, when executed by the processing circuitry, cause the processing circuitry to:
identify one or more gain values and/or one or more offset values based on a comparison between the first model of the at least one model and the second model of the at least one model, the first model of the at least one model and the third model of the at least one model, or both; and
apply the one or more gain values and/or the one or more offset values to the radii values to generate the corrected radii values.

9. The system of claim 1, wherein the second model comprises an elliptical model, and wherein the instructions, when executed by the processing circuitry, cause the processing circuitry to generate the corrected radii values by:
fitting the radii values to the elliptical model;
removing outliers from the radii values based on the fitting; and
identifying one or more malfunctioning fingers of the multi-finger caliper tool based on the outliers.

10. A method comprising:
instructing, via processing circuitry, a component of a hydrocarbon well site to adjust a position of a multi-finger caliper tool within a wellbore of a hydrocarbon well site to generate a set of measurements;
receiving, via the processing circuitry, the set of measurements indicative of an interior surface of a portion of the wellbore from the multi-finger caliper tool;
converting, via the processing circuitry, the set of measurements into a set of radii values based on at least one model of a plurality of models;
generating, via the processing circuitry, a set of corrected radii values based on the set of radii values and a second model of the plurality of models;
generating, via the processing circuitry, a defect map indicative of the portion of the wellbore based on the set of corrected radii values;
identifying, via the processing circuitry, one or more defects within the portion of the wellbore based on the defect map; and
instructing, via the processing circuitry, a display to display a graph comprising the set of corrected radii values and the defect map.

11. The method of claim 10, comprising:
instructing, via the processing circuitry, the component to adjust the position of the multi-finger caliper tool through pipes with known diameters at an ambient temperature to generate a first set of calibration data;
instructing, via the processing circuitry, the component to adjust the position of the multi-finger caliper tool through the pipes with known diameters at the ambient temperature to generate a second set of calibration data;
determining, via the processing circuitry, a plurality of gains and offsets based on a comparison between the first set of calibration data and stored calibration data and a comparison between the second set of calibration data and the stored calibration data; and
applying, via the processing circuitry, the plurality of gains and offsets after converting the set of measurements into the set of radii values.

12. The method of claim 10, comprising:
receiving, via the processing circuitry, a second set of measurements indicative of the interior surface of the portion of the wellbore from a second multi-finger caliper tool, wherein the second multi-finger caliper tool is controlled by the component;
converting, via the processing circuitry, the second set of measurements into a second set of radii values based on the at least one model;
generating, via the processing circuitry, a second set of corrected radii values based on the second set of radii values and the second model; and
aligning, via the processing circuitry, the set of corrected radii values and the second set of corrected radii values in depth, radius, azimuth, or any combination thereof.

13. The method of claim 12, comprising:
identifying, via the processing circuitry, variations in the second set of corrected radii values;
identifying, via the processing circuitry, one or more additional defects based on the variations; and
verifying, via the processing circuitry, a first defect of the one or more defects based on the one or more additional defects.

14. The method of claim 13, comprising:
incrementing, via the processing circuitry, a defect frequency of the first defect in response to the verification; and
generating, via the processing circuitry, a defect repetition map comprising an indication of the defect frequency of the first defect.

15. The method of claim 10, comprising:
determining, via the processing circuitry, a wellbore strength of the portion of the wellbore based on grouping the one or more defects and a third model of the plurality of models; and
instructing, via the processing circuitry, one or more tools to operate on the portion of the wellbore in response to determining the wellbore strength is less than a threshold wellbore strength.

16. A system comprising:
a multi-finger caliper tool configured to be positioned within a wellbore of a hydrocarbon site, wherein the multi-finger caliper tool configured to generate measurements indicative of an interior surface of the wellbore;
a component coupled to the multi-finger caliper tool and configured to adjust a position of the multi-finger caliper tool; and
a computing system communicatively coupled to the multi-finger caliper tool, the computing system comprising:
processing circuitry; and
memory storing instructions, wherein the instructions, when executed by the processing circuitry, cause the processing circuitry to perform an autonomous workflow to:
perform a first calibration of the multi-finger caliper tool by instructing the component to adjust the position of the multi-finger caliper tool through one or more pipes with known diameters to generate first calibration measurements while traversing through the one or more pipes;
instruct the component to adjust the position of the multi-finger caliper tool within the wellbore to generate the measurements while traversing through the wellbore;
perform a second calibration of the multi-finger caliper tool by instructing the component to adjust the position of the multi-finger caliper tool through the one or more pipes with known diameters to generate second calibration measurements while traversing through the one or more pipes;
convert the measurements into radii values based on the first calibration measurements, the second calibration measurements, and at least one model of a plurality of models;
generate corrected radii values based on a second model of the plurality of models;
generate a defect map indicative of a portion of the wellbore based on the corrected radii values; and
instruct a display to display the defect map.

17. The system of claim 16, wherein the instructions, when executed by the processing circuitry, cause the processing circuitry to:
identify a position of a collar within the wellbore based on the measurements;
identify a subset of measurements associated with a straight portion of the wellbore based on the position of the collar;
convert the subset of measurements into a subset of radii values based on the at least one model;
determine a corrosion level of the straight portion of the wellbore based on a comparison between the subset of radii values and a threshold radius value; and
instruct the display to display the corrosion level.

18. The system of claim 17, wherein the instructions, when executed by the processing circuitry, cause the processing circuitry to:
instruct one or more tools to operate on the portion of the wellbore in response to determining that the corrosion level is greater than a threshold corrosion threshold.

19. The system of claim 16, wherein the instructions, when executed by the processing circuitry, cause the processing circuitry to:
retrieve one or more additional measurements indicative of the interior surface of the wellbore from a database;
generate a composite measurement indicative of the interior surface of the wellbore by merging the one or more additional measurements and the measurements; and
identify one or more defects of the interior surface of the wellbore based on the composite measurement.

20. The system of claim 16, wherein the instructions, when executed by the processing circuitry, cause the processing circuitry to:
group the one or more defects based on a relative distance between each defect of the one or more defects;
determine a wellbore strength based on grouping the one or more defects and a third model; and
instruct one or more tools to operate on the portion of the wellbore in response to determining that the wellbore strength is less than a threshold wellbore strength.
